(19) United States
(12) Patent Application Publication
(10) Pub. No.: US 2015/0155901 A1
(43) Pub. Date: Jun. 4, 2015

(54) Holder for Smart Device

(71) Applicant: Patent Category Corp., Walnut, CA (US)

(72) Inventor: Yu Zheng, Walnut, CA (US)

(21) Appl. No.: 14/552,785

(22) Filed: Nov. 25, 2014

Related U.S. Application Data
(63) Continuation-in-part of application No. 14/093,650, filed on Dec. 2, 2013.

(51) Int. Cl. H04B 1/3877; A63H 33/26; H04M 1/725; G06F 1/16; H05K 5/02

(52) U.S. Cl. CPC H04B 1/3877; G06F 1/1626; H05K 5/0243; G06F 1/1647; G06F 1/1654; G06F 1/1643; H04M 1/72544; A63H 33/26

(57) ABSTRACT

An assembly has a smart device, a play object having a base with a first connector on the base, and a holder having a frame section that securely receives and retains the housing of the smart device. The holder also has a support section extending from the frame section, the support section having a second connector that is adapted to couple to the first connector on the base. The identity, and other data stored in circuits in the play objects, can be used to enable games, activities and functionalities on the smart device. Adapters relating to the play objects can be provided to add functionalities to the activities or games.

### RELATED CASES

This is a continuation-in-part of Ser. No. 14/093,650, filed Dec. 2, 2013, whose complete disclosure is incorporated by this reference as though set forth fully herein.

### BACKGROUND OF THE INVENTION

1. Field of the Invention

The present invention is directed to hand-held smart devices, and in particular, to a protective holder or case for use with tablets or smartphones.

2. Description of the Prior Art

Tablets and smartphones are widespread in today's society because of their portability and because they allow the user to transact so many aspects of their lives on them. One of the popular usages for tablets and smartphones is for gaming, and there are a variety of games that can be downloaded as “Apps” and played by the user.

### SUMMARY OF THE DISCLOSURE

It is one objective of the present invention to provide a holder for a tablet or smartphone that accommodates the coupling of play objects that can be used to enhance the gaming experience for the user.

To accomplish the objectives set forth above, the present invention provides an assembly having a smart device, a play object having a base with a first connector on the base, and a holder having a frame section that securely receives and retains the housing of the smart device. The holder also has a support section extending from the frame section, the support section having a second connector that is adapted to couple to the first connector on the base.

Circuitry can be provided in the base of the play objects, and in the support section, so that the identity of the play objects can be communicated from the base to the support section, and then from the support section to the smart device. The identity, and other data stored in these circuits, can be used to enable games, activities and functionalities on the smart device. Adapters relating to the play objects can be provided to add functionalities to the activities or games.

### BRIEF DESCRIPTION OF THE DRAWINGS

FIG. 1 is a perspective view of a holder according to one embodiment of the present invention.

FIGS. 2A-2C illustrate three different play objects that can be coupled to the holder of FIG. 1.

FIG. 3 is an exploded perspective view illustrating the holder of FIG. 1, the play objects of FIGS. 2A-2C, and a tablet.

FIG. 4 illustrates the holder, play objects and tablet of FIG. 3 combined together in use.

FIG. 5 is an exploded perspective view of a holder according to another embodiment of the present invention.

FIGS. 6A-6C illustrate modifications that can be made to the play objects of FIGS. 2A-2C.

FIG. 7 is a schematic diagram for the system shown in FIG. 5.

FIG. 8 is an exploded perspective view illustrating a holder according to the present invention that is shown in use with a smartphone.

FIG. 9 is a perspective view of a holder in accordance with another embodiment of the present invention, shown in use with a tablet, play objects and another interactive display.

FIG. 10A is a perspective view of a holder in accordance with yet another embodiment of the present invention.

FIG. 10B is an exploded perspective view of the holder of FIG. 10A shown in used with tablets of different size.

FIG. 10C is a side-plan view showing the holder of FIG. 10A used with a tablet of a certain size.

FIG. 10D is a side-plan view showing the holder of FIG. 10C in use with a tablet that is larger than the tablet shown in FIG. 10C.

FIG. 11 is a perspective view of a holder in accordance with a further embodiment of the present invention.

FIG. 12 is a perspective view of a holder in accordance with another embodiment of the present invention, shown in use with a tablet, play objects and a different interactive display.

FIG. 13A is an exploded perspective view illustrating the holder and play objects of FIGS. 3-4 shown in use with a different connector.

FIG. 13B is an exploded perspective view illustrating the support section and a play object of FIGS. 3-4 shown in use with yet another different connector.

FIG. 14 illustrates a play object supported on the studs of the support section.

FIG. 15 illustrates a support section according to a different embodiment of the present invention.

FIG. 16 is an exploded bottom perspective view of a play object.

FIG. 17 is an exploded perspective view illustrating a holder, play objects and adapter blocks according to another embodiment of the present invention.

FIG. 18 is an exploded view illustrating a play object and an adapter block according to the embodiment of FIG. 17.

FIG. 19 is an exploded view illustrating another play object and another adapter block according to the embodiment of FIG. 17.

### DETAILED DESCRIPTION OF THE PREFERRED EMBODIMENTS

The following detailed description is of the best presently contemplated modes of carrying out the invention. This description is not to be taken in a limiting sense, but is made merely for the purpose of illustrating general principles of embodiments of the invention. The scope of the invention is best defined by the appended claims.

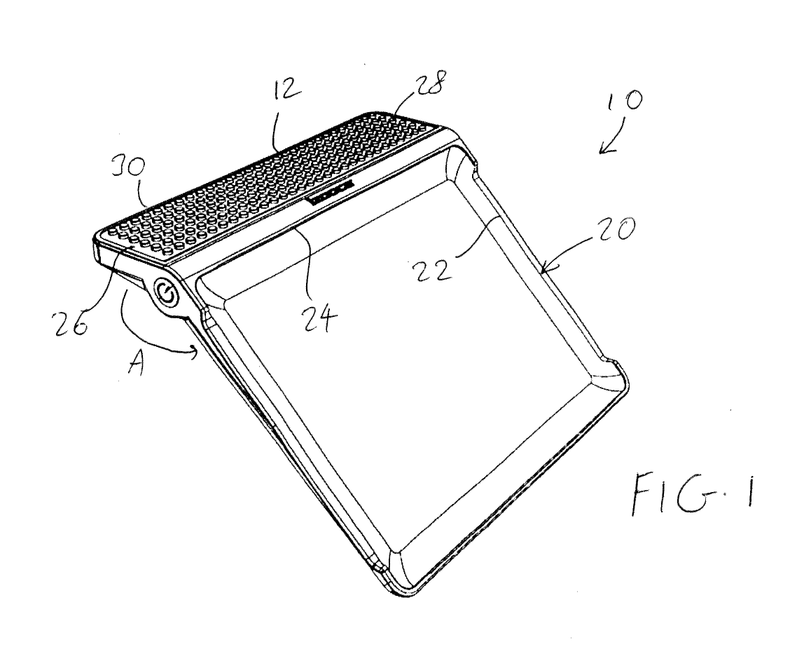

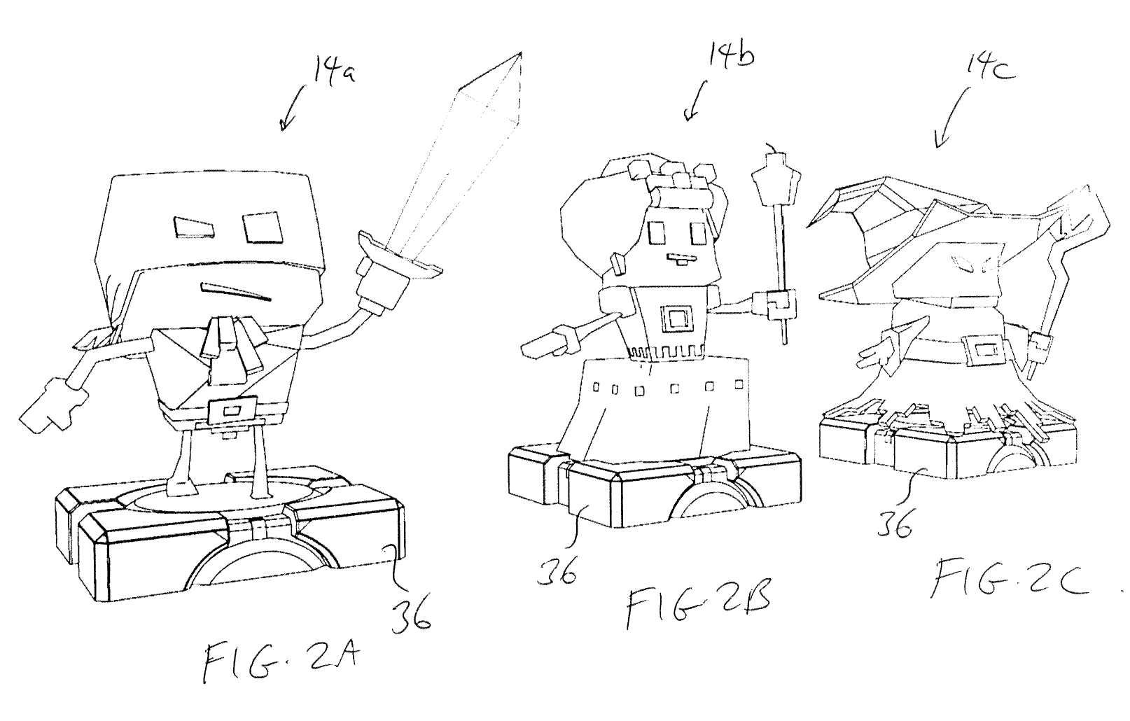

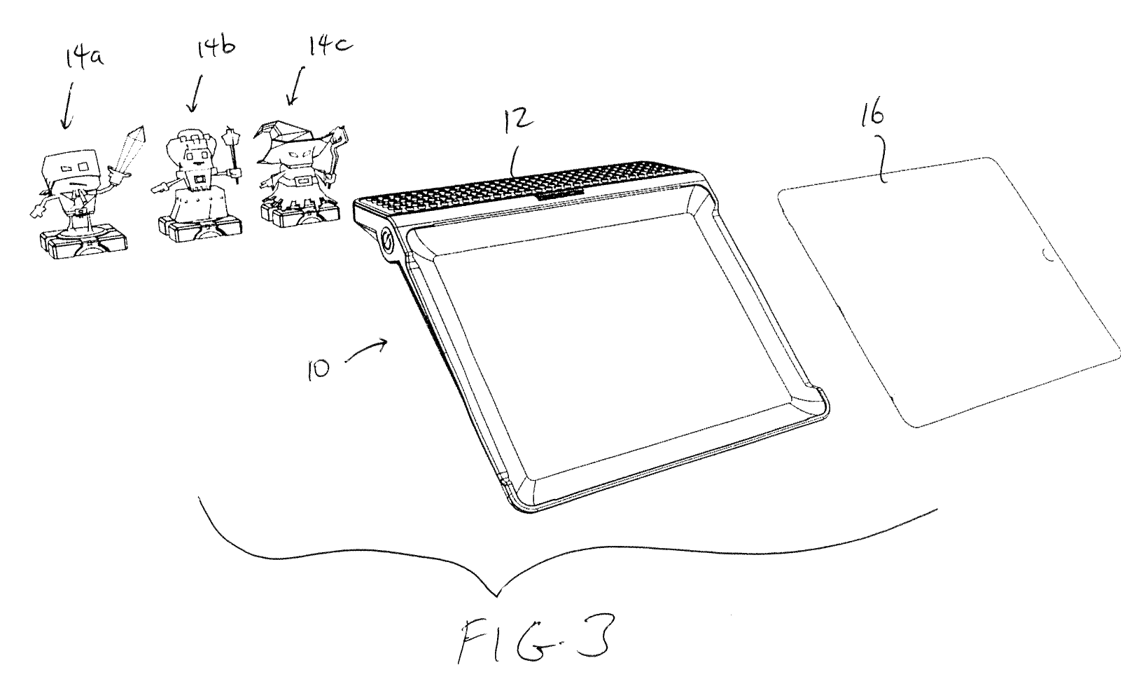

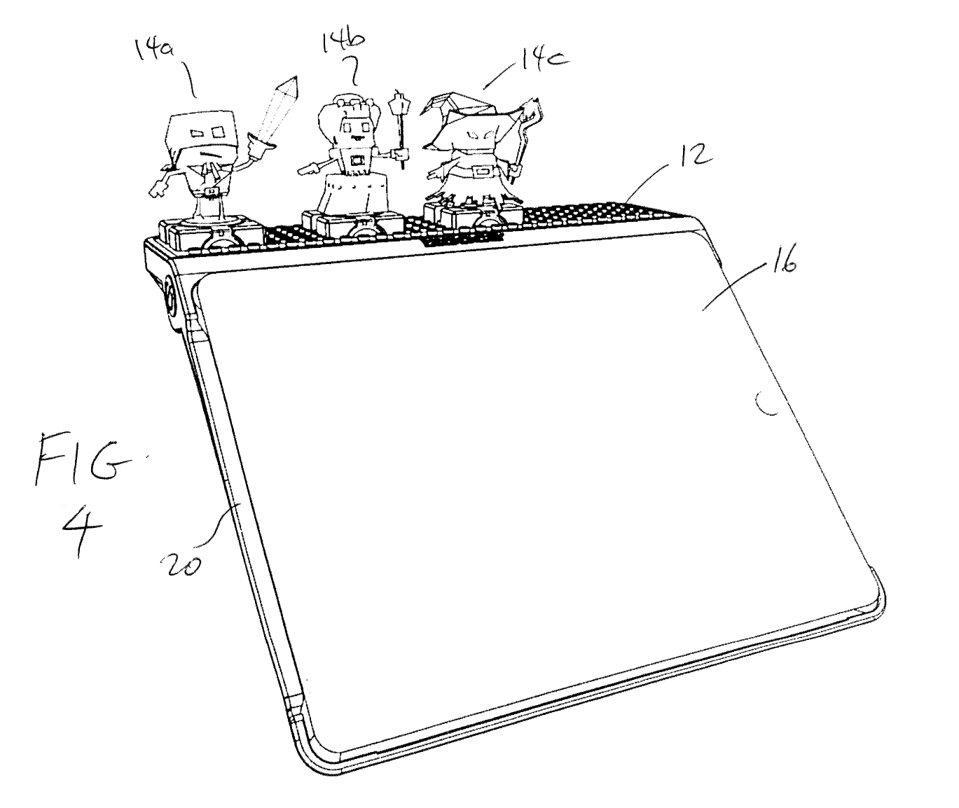

FIGS. 1-4 illustrate a holder 10 according to one embodiment of the present invention. The holder 10 has a support section 12 that allows a plurality of play objects 14a, 14b and 14c to be coupled thereto. An interactive computing device, such as a tablet 16, is received inside the holder 10. The tablet 16 can be any conventional tablet, such as an iPAD™ or other smart tablet.

The holder 10 has a four-sided frame section 20 that is sized, configured and adapted to surround a conventional tablet 16. The frame section 20 can be made from any solid material that is somewhat flexible, such as PVC, rubber, plastics and materials similar to those used for conventional smartphone protection cases. Flanges 22 can be provided along the internal edges of the frame section 20 and function to retain the housing of the tablet 16 inside the periphery of the frame section 20. Other techniques or mechanisms (e.g., VELCRO™ pads, ties, tabs, etc.) can also be used to retain the housing of the tablet 16 inside the periphery of the frame section 20.

The support section 12 can extend along any portion of one of the edges or sides of the frame section 20. For example, the support section 12 is shown as extending along the entire edge or side 24, but the support section 12 can also extend along a central portion, and not along the entire length, of the edge or side 24. The support section 12 can also be provided along another side or edge. The support section 12 defines a planar upper surface 26 that has a plurality of studs 28 provided thereon. The support section 12 and its studs 28 can be made of the same material as the frame section 20, or from a different material. The plane of the support section 12 is preferably positioned at an angle A away from the plane of the frame section 20. The angle A is preferably between 90 degrees and 180 degrees so that the support section 12 can be used to prop the tablet 16 at an angle for convenient viewing, with the rear edge 30 of the support section 12 contacting a table or other flat surface. It is also possible to provide the support section 12 separate from the frame section 20 so that the support section 12 is pivotable with respect to the frame section 20.

Each play object 14a-14c has a character or object that is supported on a base 36. The base 36 is adapted to be coupled to the studs 28 on the support section 12 in a manner that is similar to a LEGO™ connection. Specifically, most LEGO™ brick pieces have two basic components: studs on top and tubes on the inside. A brick's studs are slightly bigger than the space between the tubes and the walls. When the bricks are pressed together, the studs push the walls out and the tubes in. The material is resilient and wants to hold its original shape, so the walls and tubes press back against the studs. Friction also plays a role, preventing the two bricks from sliding apart. This stud-and-tube coupling system uses an interference fit, which provides a firm, friction-based connection between two parts without the use of an additional fastener. Thus, the bottom of the bases 36 would also include the tubes and walls that are normally found at the base of a conventional LEGO™ brick.

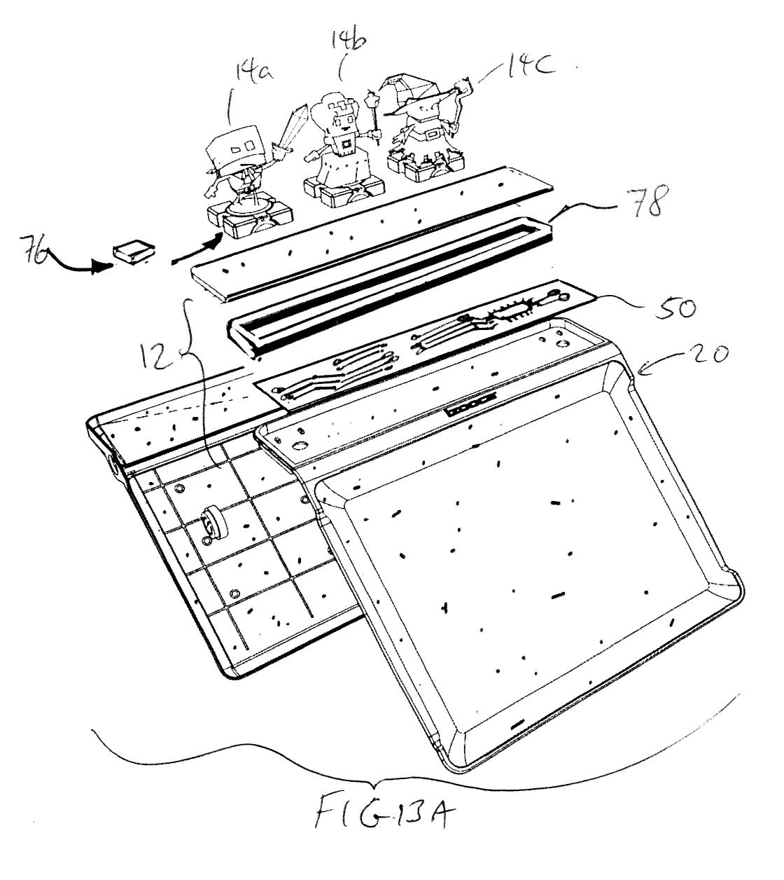

Referring to FIGS. 13A and 13B, it is possible to use different forms of connectors to hold the play objects 14a-14c to the support section 12. In FIG. 13A, a steel loop or magnet 78 can be positioned inside the support section 12, and a magnetic block 76 can be secured to the bases 36 of the play objects 14a-14c, so that the play objects 14a-14c can be supported on the support section 12 through the magnetic forces during use. In FIG. 13B, the base 36 of each play object (e.g., 14a) can be provided with a shaft or projection 90 which is adapted to be inserted into openings 92 provided in the upper surface of the support section 12.

FIG. 4 illustrates a tablet 16 held in place inside the frame section 20, and the play objects 14a-14c coupled to the upper section 12. In this configuration, the user can play a game involving these play objects 14a-14c. For example, a user can use the tablet 16 to take a photo of any of these play objects 14a-14c, and the application that has been downloaded onto the tablet 16 can recognize the play objects 14a-14c from the photographed image(s) and enable the start of an activity (e.g., game, song, story, etc.) relating to the play objects 14a-14c.

Alternatively, the holder 10 can be used solely as a toy holder for holding play objects 14a-14c. It is not necessary to place a smart device in the frame section 20.

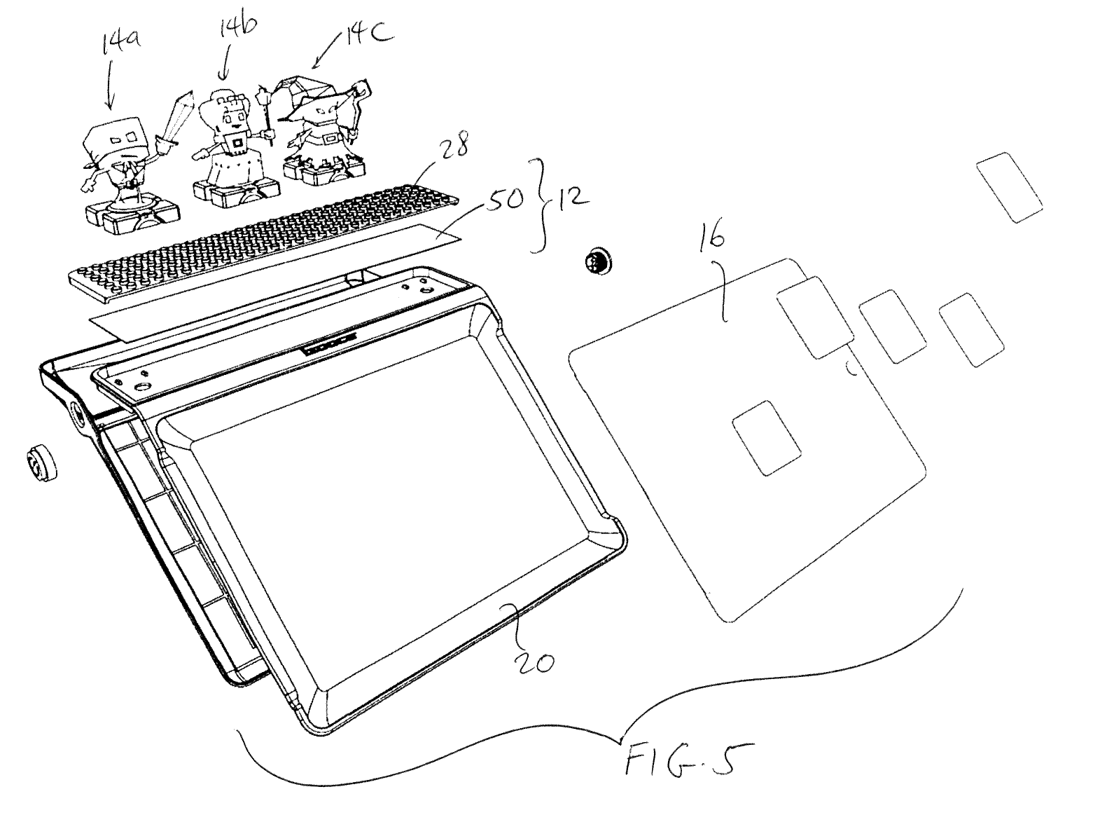

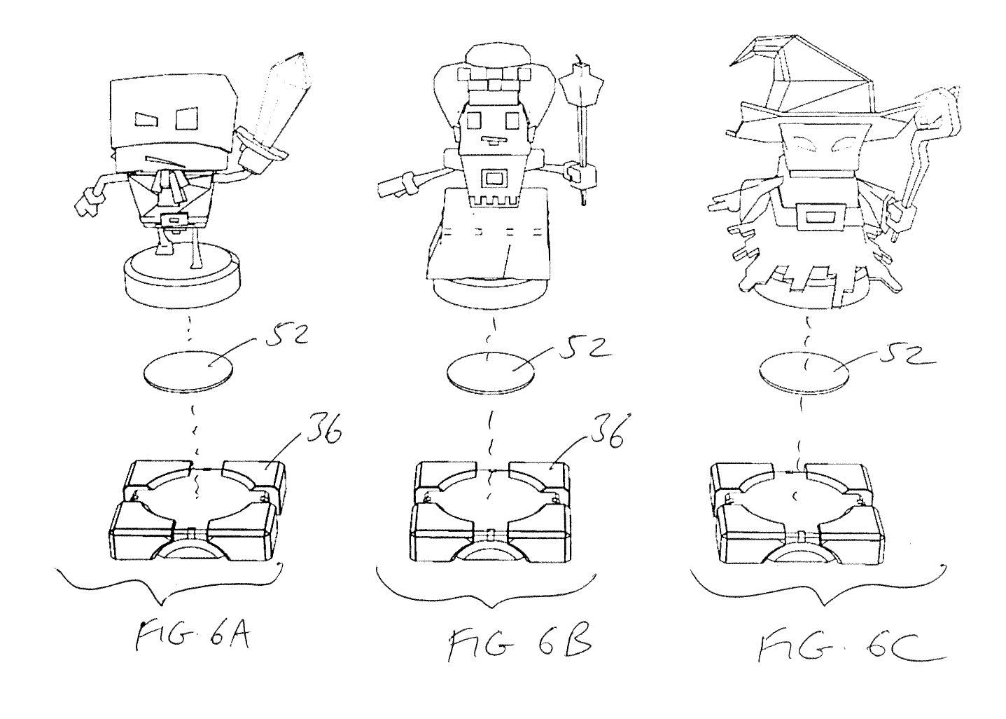

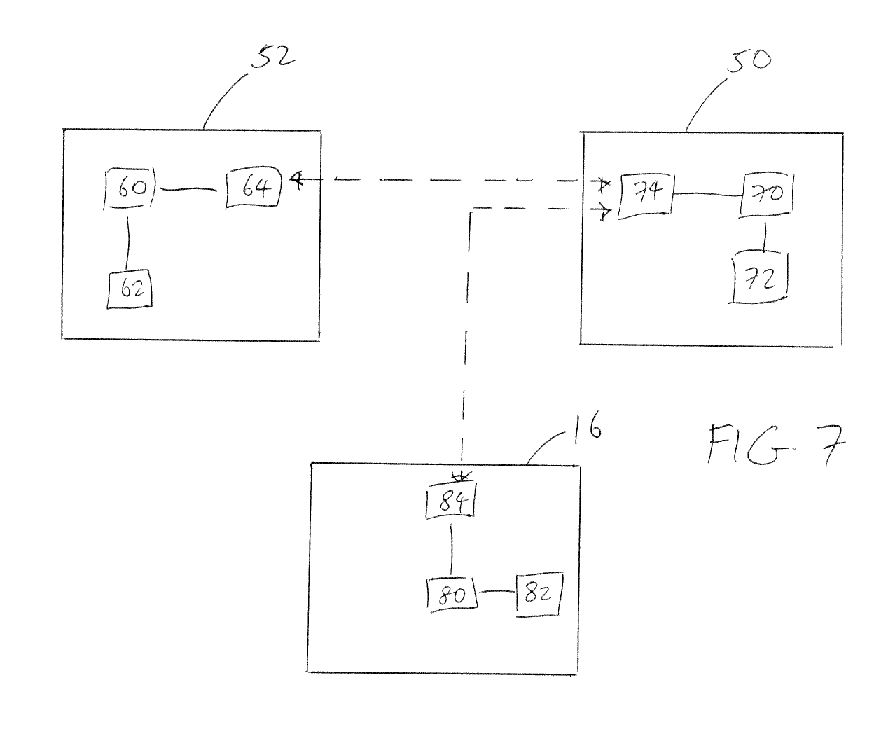

FIGS. 5-7 illustrate another embodiment of the present invention. In FIGS. 5-6C, the support section 12 can be a housing that retains a circuit board 50 inside. The circuit board 50 can include a circuitry that is adapted to communicate with the circuitry on the circuit board 52 inside the base 36 of the play objects 14a-14c.

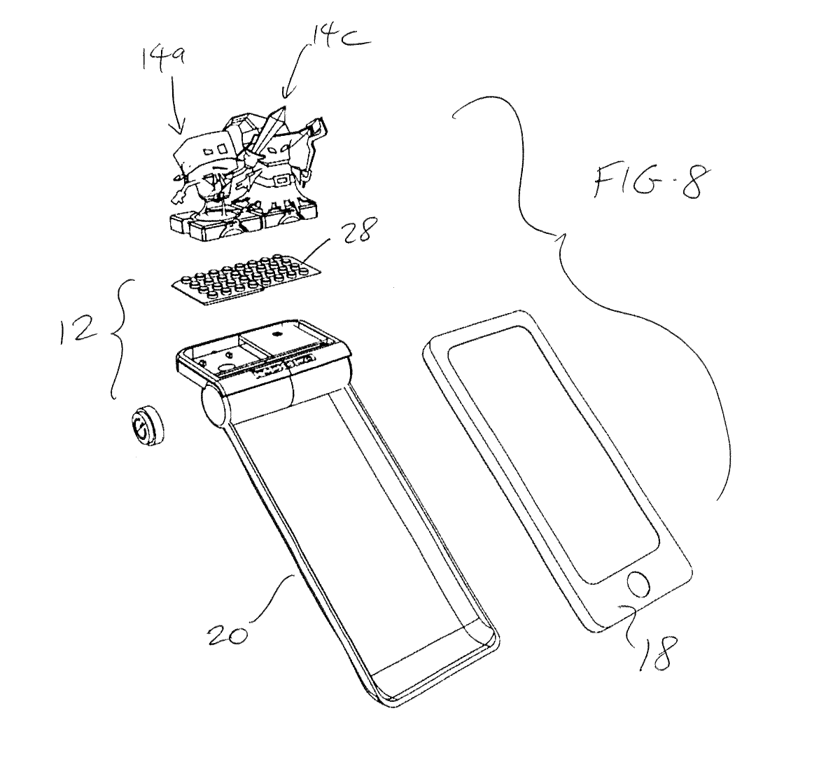

Referring to FIG. 7, the circuit board 52 in each play object 14a-14c can include a processor 60, a memory 62 and an antenna 64. The memory 62 can store codes that identify the play object, as well as data that contain details or characteristics of the play object. Alternatively, the memory 62 can include a radio-frequency identification (RFID) tag that stores identification for the object. Similarly, the circuit board 50 in the support section 12 can include a processor 70, a memory 72 and an antenna 74. The memory 72 can store programs, codes, and other data. The circuit board 50 can also include an RFID reader coupled to the antenna 74 for reading the RFID tag on the circuit board 52.

In use, when the play objects 14a-14c have been coupled to the support section 12, the processor 60 can communicate with the processor 70 via the antennas 64 and 74. The processor 60 can access the codes and data in the memory 62, and provide them to the processor 70. The processor 70 can then access the programs and other data in the memory 72, and send appropriate signals via its antenna 74 to the tablet 16. The tablet 16 can also have a processor 80, a memory 82 and an antenna 84. The signals communicated from the antenna 74 are received at the tablet 16 via the antenna 84 and the processed by the processor 80. Alternatively, if the objects 14a-14c are provided with RFID tags, the RFID reader on the circuit board 50 can read the identification signals and communicate via conventional BLUETOOTH™ technology with the tablet 16. The signals received by the tablet 16 can trigger an activity (such as stories, games, reading a book, etc.) with the character or object displayed on the tablet 16 during the activity.

For example, when the play object 14a has been coupled to the support section 12, it communicates its identity to the processor 70 in the support section 12, which then communicates this identity to the processor 80 in the tablet 16. With the downloaded application being enabled, the application will recognize the identity of the play object 14a, and enable an activity (e.g., game, story, video, song, etc.) relating to that play object 14a to be played by a user on the tablet 16. At this point, the processor 80 can request additional data (e.g., code, details, etc.) from the processor 60 via the processor 70, and the processor 60 can access the memory 62 for the requested data and transfer the data back to the processor 80. A variety of activities can be played through the back-and-forth communication between the play object and the application running on the tablet 16, using the circuit board 50 in the support section 12 as an intermediary. The play object 14a can be displayed on the tablet 16 during the activity, and interacts with the user during the activity.

The user can also participate and make the activity more interactive. For example, if the activity is a game, the user can cause the image of the play object to move, to engage in specific acts, or be involved in the game in any known manner. If the activity is the reading of a book or the playing of a song, the user can make the image of play object to engage in certain acts or activities during the reading of the book or playing of the song by selecting certain options, or by directly manipulating the position of the image of the play object on the screen of the smart device. Such manipulation can also enable different functionalities. For example, during a game, a song or reading is enabled if the user manipulates the image in a certain way, or selects certain controls. These activities can be provided by software on the selected “App”, and/or the data or other information stored in any of the memories 62 or 72.

Even though the present invention has been described in a connection with a tablet 16, it is also possible to apply the principles herein to a holder for a smartphone. FIG. 8 illustrates a holder 10 that can be used with a smartphone 18.

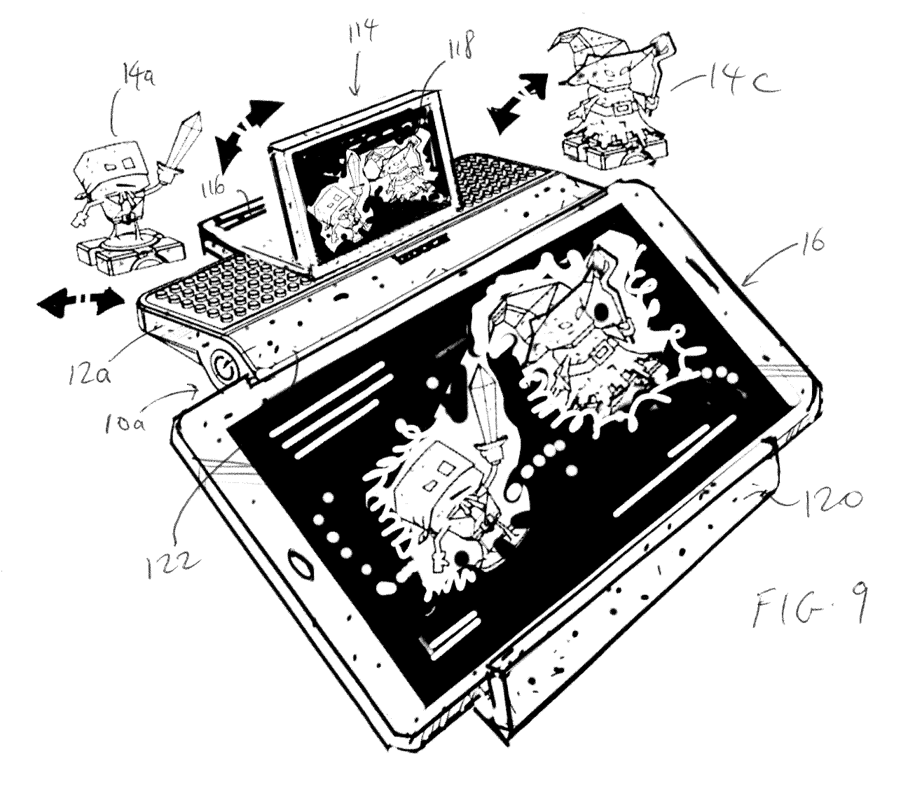

FIG. 9 illustrates another embodiment where a holder 10a is shown holding a tablet 16 as in FIG. 4, with play objects 14a, 14c removably coupled to the support section 12a of the holder 10a. In addition to the play objects 14a and 14c, an interactive display 114 can also be removably coupled to the support 12a via a connecting plate 116 that can be part of the display 114. For example, the plate 116 can define a clip for clipping or gripping the support section 12a, or the bottom of the plate 116 can have the tubes and walls that are normally found at the base of a conventional LEGO™ brick to connect the plate 116 to the studs on the support section 12a. The plate 116 can be angled with respect to the screen 118 so that the screen 118 can be supported on the support section 12a at a predetermined angle. The angles at which the tablet 16 and the screen 118 are positioned can be different, and be adjusted to allow the user to have an optimum viewing angle for the two screens (i.e., screen 118 and the screen on the tablet 16) so that the user can view these two screens without having any glare or undesirable reflections coming off either of the screens. The display 114 can also have a circuit board that can be the same as circuit board 52 described above, but with the processor 60 electrically coupled to the screen 118 for displaying images. These images can be the same as the images displayed on the tablet 16, or images that are different from the images displayed on the tablet 16. This allows the user to play an interactive game, or access information or data, and be able to view different playing fields or scenes (for games), images, facts or data from different sources.

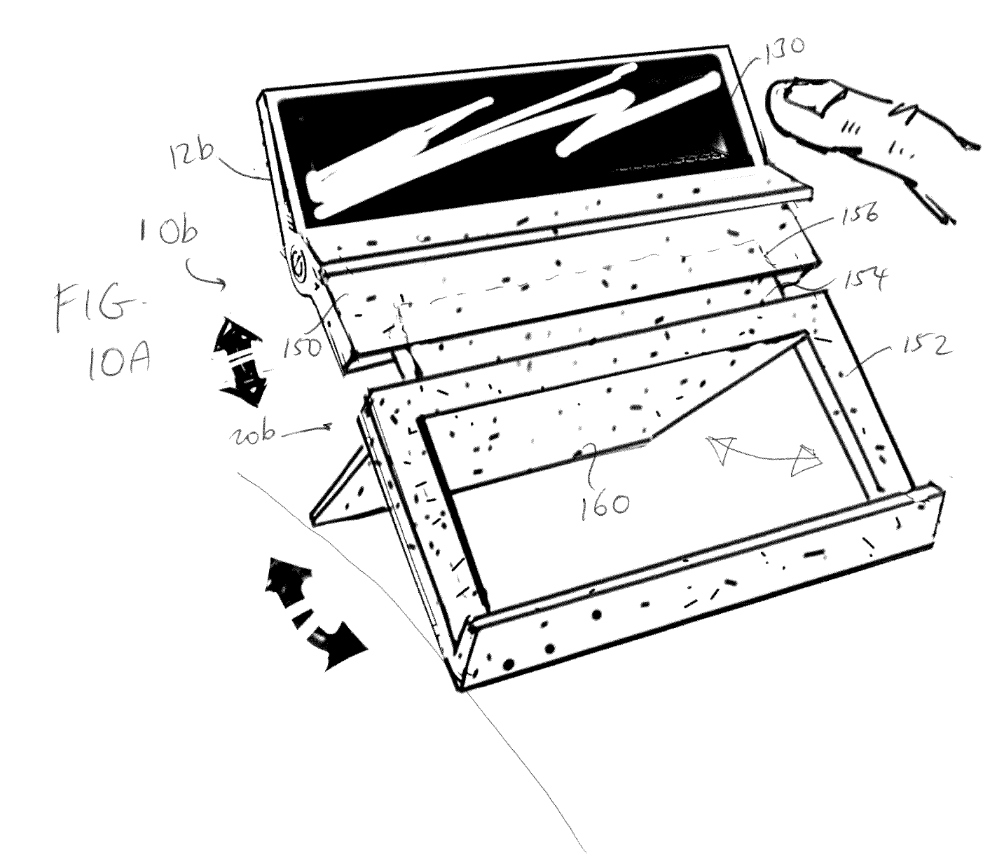

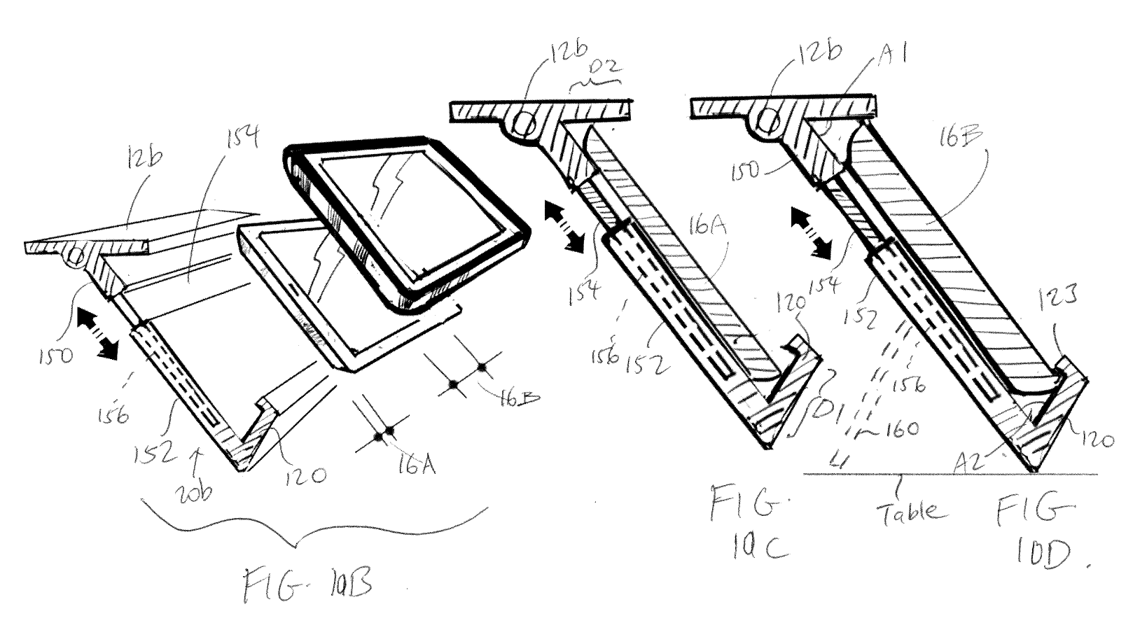

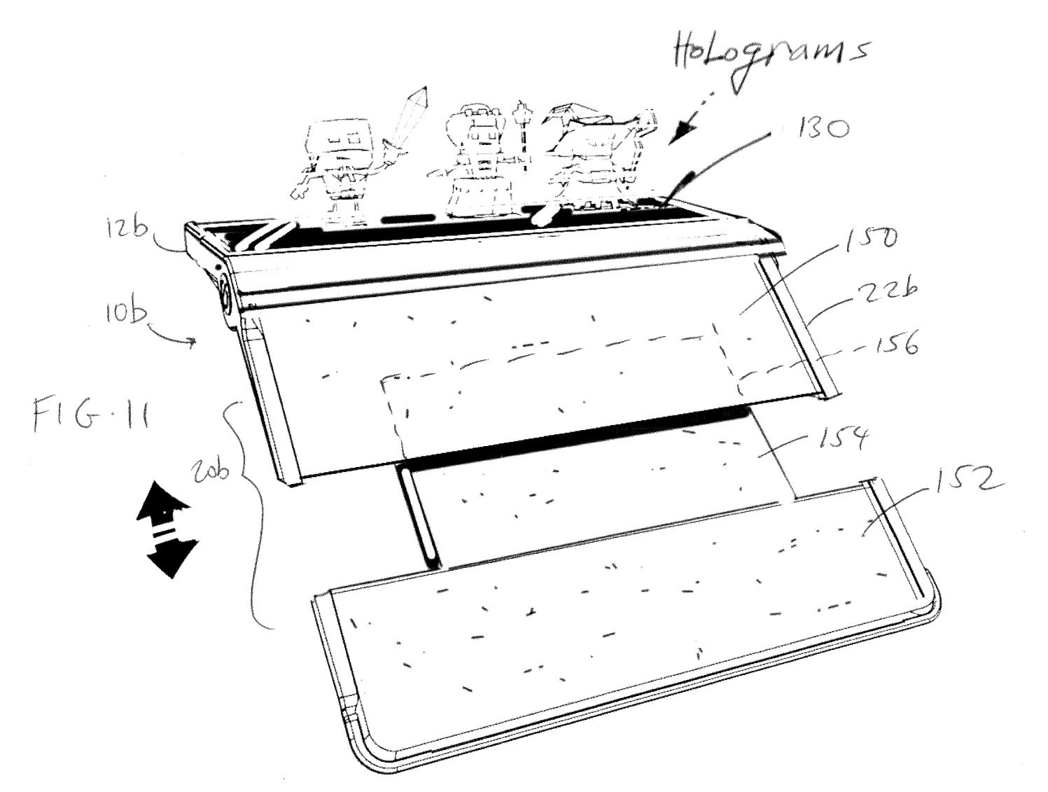

In addition, the holder 10a can be slightly different from the holder 10 in that the flanges 22 can be replaced by a bottom bar 120 and a top flange edge 122 that allow the bottom surface of the tablet 16 to rest against the bottom bar 120 and the top edge of the tablet 16 to be clipped or received inside the top flange edge 122, so as to hold the tablet 16 at the holder 10a. It is also possible to have the support section 12 extend forwardly (see FIGS. 10B-10D) so that the front edge of the support section 12 acts as a top flange edge for holding or supporting one edge of the tablet 16.

FIG. 10A illustrates another holder 10b according to another embodiment of the present invention. The support section is now a pivotable housing 12b that can also function to prop up and support the tablet 16 at an angle, but does not have connectors. Instead, the pivotable housing 12b houses a screen 130. The combined housing 12b and screen 130 can be the same as the interactive display 114 and screen 118 in FIG. 9, and can include a circuit board 52 that communicates its signals directly with the processor 80 of the tablet 16. As a result, this housing 12b and its screen 130 can perform the same functions as the display 114 and its screen 118. The screen 130 can also be a touch-screen so that the user can enter inputs or manipulate data by touching icons or symbols on the screen 130.

In addition, as shown in FIG. 11, holograms of the toy objects 14a, 14b and 14c can be produced by the housing 12b. The housing 12b can include the components (e.g., lasers, photographic plates and mirrors) that are normally needed for recording and reconstructing/producing conventional holograms of the images of the toy objects 14a, 14b and 14c. The holograms can be produced using components and techniques that are well-known in the art, and embodied in the housing 12b.

Most tablets are used with a protective cover, and the conventional protective covers will vary in shape and size. Therefore, there is a need for the size and shape of the frame 20b of the holder 10b to be adjustable. Referring to FIGS. 10A, 10B and 11, the frame 20b of the holder 10b can also be adjusted to receive tablets 16 and protective covers (with tablets 16 held therein) having different sizes and shapes.

This frame 20b is different from the frame 20 of the other embodiments. The frame 20b can have two hollow backboard sections 150 and 152, with a guiding piece 154 positioned along a track 156 or space inside the hollow sections 150 and 152. The sections 150 and 152 travel along the guiding piece 154 between two positions, a first position (as shown in FIGS. 10A and 11) where the sections 150 and 152 are separated so that the combined sections 150 and 152 can support a larger tablet 16 or a tablet 16 with a larger cover (see FIG. 10B), and a second position where the sections 150 and 152 are abutting each other so that the combined sections 150 and 152 can support a smaller tablet 16. A pivotable flap 160 (see FIG. 10A) can be provided in the section 152 so that the flap 160 can be pivoted to act as an easel to support the tablet 16 at an angle on a table or surface. The frame 20b can utilize a bottom bar 120b to hold the tablet 16 (see FIGS. 10A-D), or can utilize flanges 22b (see FIG. 11) to hold the tablet 16.

FIG. 10B shows that the frame 20b can be used with tablets 16A and 16B of different sizes. For example, tablet 16B is shown having a cover but tablet 16A does not have a cover (or has a smaller cover). FIG. 10C shows the amount of extension needed between the sections 150 and 152 to accommodate the smaller tablet 16A, while FIG. 10D shows the (larger) amount of extension needed between the sections 150 and 152 to accommodate the larger tablet 16B.

FIGS. 10C and 10D also illustrate the angles A1 and A2 that allow a tablet 16 to be supported in the holder 10b. These angles A1 and A2 are selected to optimize the viewing angle of the screen of the tablet 16. The angle A1 is the angle between the front edge of the support section 12b and the section 150, while the angle A2 is the angle between the bottom bar 120 and the section 152. The angles A1 and A2 are preferably less than 90 degrees, and can be adjusted to provide the optimum viewing angle for the screen of the tablet 16 when the tablet is supported on a table by the flap 160. In this regard, the bottom bar 120 has a depth D1, and the depth D1 of the bottom bar 120 works in conjunction with the depth D2 of the extending front edge of the support section 12b to allow for tablets of different sizes to be adjustably supported. Specifically, the depth D1 allows tablets 16A and 16B of different thicknesses to be fitted inside (compare FIGS. 10C and 10D). Also, for the front edge of the support section 12b to grip or hold the upper edge of the tablet 16A or 16B, the depth D2 must extend for a sufficient distance. For example, FIG. 10D shows a thicker tablet 16B having its top edge contact the front of the front edge of the support section 12b, and the bottom edge of the tablet 16B at the front of the bottom bar 120 adjacent its hooked end 123.

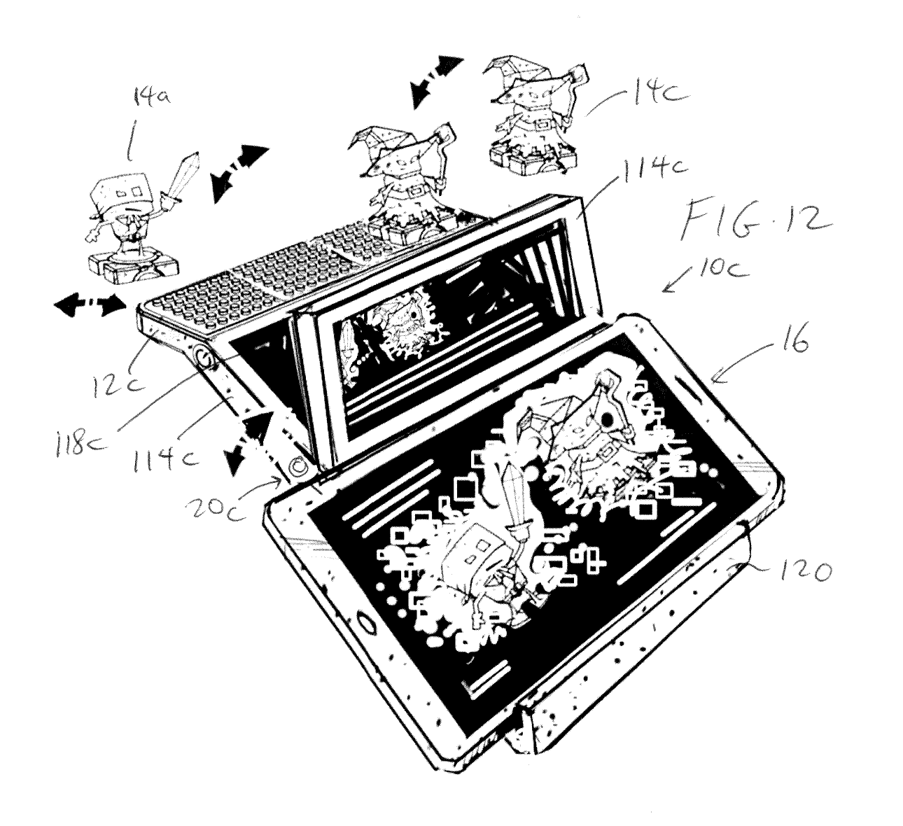

FIG. 12 illustrates modifications that can be made to the embodiment in FIG. 9. Here, the separate display 114 is now a display 114c that is integrated with the frame 20c and the support section 12c. Specifically, the housing for the display 114c is now pivotably connected to the frame 20c and pivotably connected to the support section 12c so that it connects the frame 20c at an angle to the support section 12c. In this manner, the two screens (114c and the screen on the tablet 16) can be pivoted with respect to each other to provide the optimum viewing angles for these two screens with respect to each other.

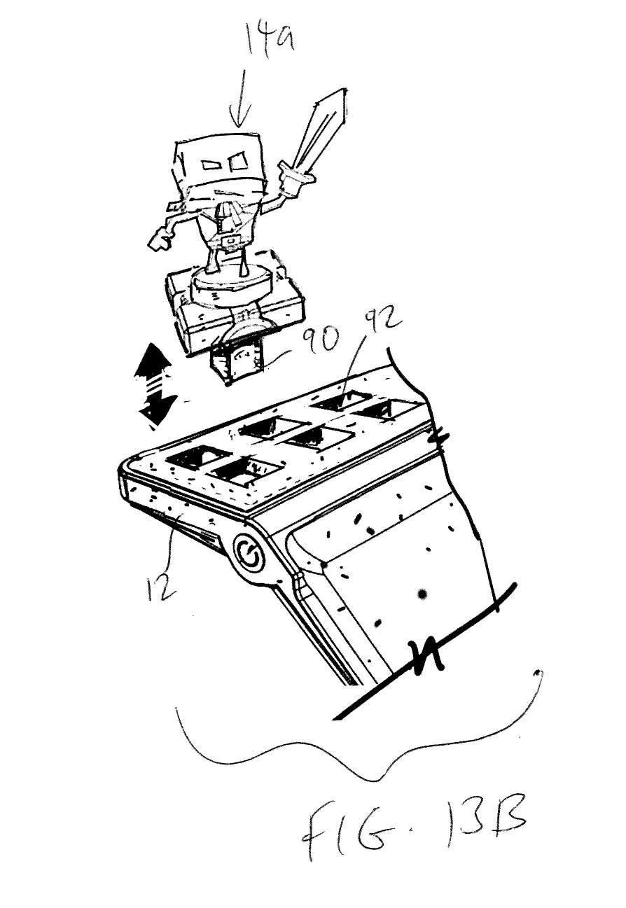

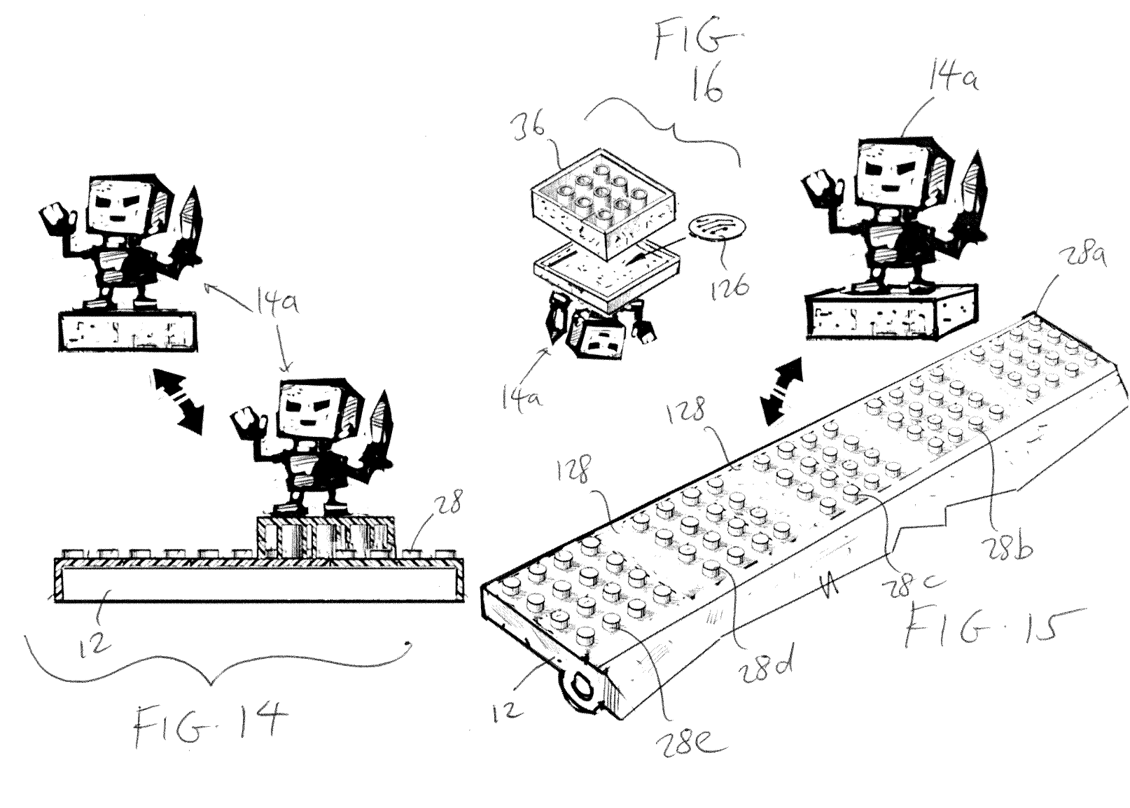

FIGS. 14-16 illustrate another embodiment of the present invention where the studs 28 on the top of the support section 12 can be organized into groups or clusters of studs 28. Specifically, the studs can be organized into five groups of studs 28a, 28b, 28c, 28d and 28e, with each group being arranged as an n×n array (e.g., as shown in FIG. 15, a 4×4 array for 16 studs). A gap 128 separates adjacent groups of studs 28a, 28b, 28c, 28d and 28e. These groups of 28a, 28b, 28c, 28d and 28e assist the user or player in positioning the play object 14a within the correct zone or area on the top of the support section 12. This positioning can be important in the embodiment where multiple play objects are intended to be positioned on the support section 12. For example, each play object (14a and others) can be provided with an RFID chip 126 on the inside of its base 36. The RFID chip 126 can contain the identity of the play object 14a, with the identity communicated using known signal transmission techniques to a plurality of antennas on the circuit board 50 inside the support section 12. For example, an antenna positioned underneath the group of studs 28a will detect the identity of a play object positioned on the group of studs 28a, another antenna positioned underneath the group of studs 28b will detect the identity of another play object positioned on the group of studs 28b, and so on. In addition, the gap 128 provides a certain type of spacing between adjacent play objects so that arms or other parts of a play object that encroach beyond the space of the group of studs 28 will not encroach into another area defined by another group of studs. Finally, providing separate and discrete groups of studs will allow a maximum number of play objects to be organized and positioned on the support section 12.

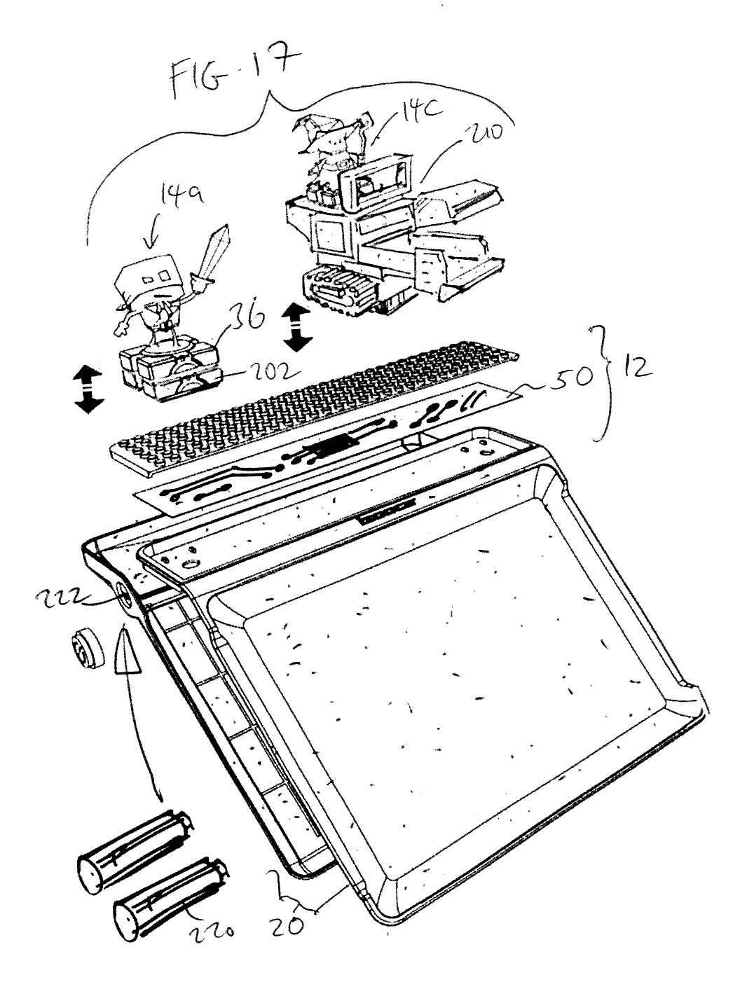

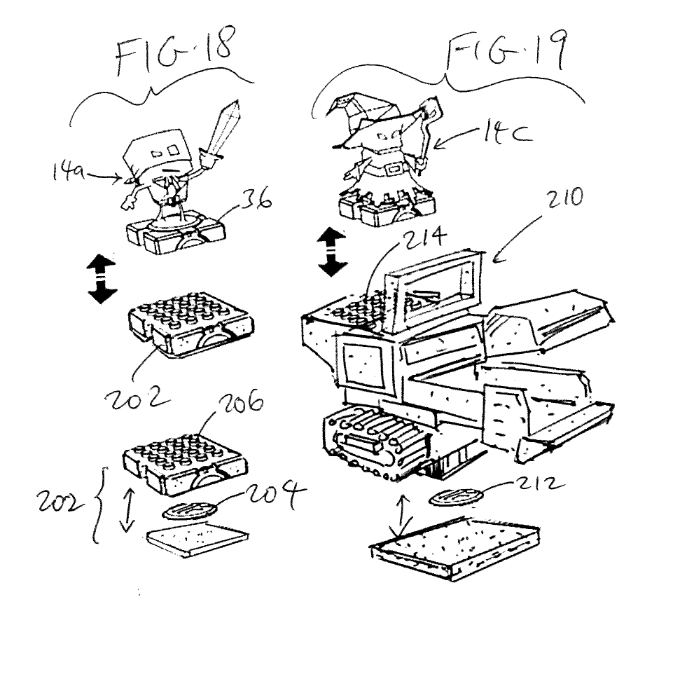

FIGS. 17-19 illustrate another embodiment of the present invention, where adapter blocks can be used to add functionalities to the play objects. Specifically, as shown in FIGS. 17 and 18, the play object 14a can be used with an adapter block 202. The adapter block 202 can be embodied in its simplest form as a simple block that houses an RFID chip 204. The top surface of the block 202 can be provided with connectors (e.g., studs 206), so that the base 36 of the play object 14a can be removably coupled to the top surface of the block 202. Also, the bottom surface of the block 202 can have connectors for coupling to the studs 28 on the support section 12. In use, the RFID chip 204 of each adapter block 202 will contain an identity that can be detected by the circuit board 50 via RFID communication techniques that are well-known in the art. The processor 70 on the circuit board 50 will detect the identities of the block 202 and the play object 14a (which can have its own RFID chip that transmits the identity of the play object 14a to the processor 70), and then apply the functionalities from the block 202 to the play object 14a during the game or activity that is being played on the tablet 16. These functionalities can include different activities, different powers (e.g., the character is provided with another weapon or characteristic), or access to different locations or relationships.

As shown in FIGS. 17 and 19, the adapter block can be embodied in the form of another object, such as a vehicle 210 like a bulldozer. An RFID chip 212 can be housed in the vehicle 210 for transmitting its identity to the processor 70. The vehicle 210 can also have connectors 214 (such as studs) for removably coupling the play object 14c. In this embodiment, different blocks 202 and 210 can be used with different play objects 14a, 14c to provide a wide variety of different play options.

In addition, as shown in FIG. 17, batteries 220 can be inserted into a battery compartment 222 in the support section 12 for powering the circuit board 50 and any auxiliary screens (e.g., 130 and 114c).

Thus, the present invention provides a multi-purpose holder that can be used with a tablet or smartphone, which allows objects to be supported on the holder for play and other activities that are interactive with the tablet or smartphone. This enhances the enjoyment and utility of the tablet or smartphone by enhancing a game or activity that is being played on the tablet or smartphone. The holder can also function to prop up the tablet smartphone at an angle to facilitate convenient viewing.

While the description above refers to particular embodiments of the present invention, it will be understood that many modifications may be made without departing from the spirit thereof. The accompanying claims are intended to cover such modifications as would fall within the true scope and spirit of the present invention.

What is claimed is:

1. An assembly, comprising:
a smart device having a housing and a first display screen;
a play object having a base with a first connector on the base; and
a holder having a frame section that securely receives and retains the housing of the smart device, a support section extending from the frame section, the support section having a second connector that is adapted to couple to the first connector on the base, and a second display screen coupled to the support section.

2. The assembly of claim 1, wherein the second display screen is removably coupled to the support section.

3. The assembly of claim 1, wherein the second display screen is pivotably coupled to the frame section.

4. The assembly of claim 1, wherein the second display screen is pivotably coupled to the support section.

5. The assembly of claim 1, wherein the second display screen is a touch screen.

6. The assembly of claim 1, wherein the first connector is a magnet.

7. The assembly of claim 1, wherein the first connector is a shaft and the second connector is an opening.

8. The assembly of claim 1, wherein the support section houses a first circuitry, and wherein the base of the play object houses a second circuitry that communicates with the first circuitry.

9. The assembly of claim 8, wherein the first circuitry includes a memory that stores the identity of the play object, and means for communicating the identity of the play object to the second circuitry.

10. An assembly, comprising:
a smart device having a housing;
a play object having a base with a first connector on the base;
a holder having a frame section that securely receives and retains the housing of the smart device, and a support section extending from the frame section, the support section having a plurality of second connectors, with each second connector adapted to couple to the first connector on the base, and with each of the plurality of second connectors separated by a spacing.

11. The assembly of claim 10, wherein each of the second connectors comprises an array of studs.

12. An assembly, comprising:
a smart device having a housing;
a play object having a base with a first connector on the base, the base housing a first circuit;
an adapter having a housing that houses a second circuit, the adaptor having a second connector that is adapted to couple to the first connector on the base, and a third connector;
a holder having a frame section that securely receives and retains the housing of the smart device, and a support section extending from the frame section, the support section housing a third circuit, the support section having a fourth connector, with the fourth connector adapted to couple to either the first connector on the base or the third connector on the adapter; and
wherein the first and second circuits communicate with the third circuit to enable an activity or functionalities on the smart device.

13. The assembly of claim 12, wherein the adapter is another play object.
